(19) United States
(12) Patent Application Publication
(10) Pub. No.: US 2024/0271285 A1
(43) Pub. Date: Aug. 15, 2024

(54) COMPONENT WITH INTEGRATED ALUMINUM DIFFUSION LAYER AND ALUMINUM OXIDE LAYER

(71) Applicant: KAMAX Holding GmbH & Co. KG, Homberg (Ohm) (DE)

(72) Inventor: Ali Solimani, Marburg (DE)

(73) Assignee: KAMAX Holding GmbH & Co. KG, Homberg (Ohm) (DE)

(21) Appl. No.: 18/290,708

(22) PCT Filed: Jul. 20, 2022
(86) PCT No.: PCT/EP2022/070297

§ 371 Date: Jan. 19, 2024

(30) Foreign Application Priority Data
Jul. 20, 2021 (DE) 10 2021 118 766.4

(51) Int. Cl. C23C 28/00; C21D 1/18; C21D 1/74; C23C 8/10; C23C 10/60

(52) U.S. Cl. CPC C23C 28/345; C21D 1/18; C21D 1/74; C23C 8/10; C23C 10/60; C23C 28/322

(57) ABSTRACT

A component with a component (1) of low-alloy steel and/or heat-treatable steel is provided, wherein the component (1) is at least partially coated with an aluminum diffusion layer (10) and an aluminum oxide layer (14) is applied to the aluminum diffusion layer (10), wherein the layer thickness of the aluminum diffusion layer (10) is 1-200 μm, wherein the aluminum diffusion layer (10) has an aluminum content, based on the total weight of the aluminum diffusion layer, of 10 wt. % above the aluminum content of the steel up to a maximum concentration, wherein the aluminum content in the aluminum diffusion layer (10) increases in the direction of the interface (12) between the aluminum diffusion layer (10) and the aluminum oxide layer (14) from 10% by weight up to the maximum concentration, and wherein the maximum concentration is 11-60% by weight.

### CROSS-REFERENCE TO RELATED APPLICATIONS

This application is a U.S. National Stage Application under 35 U.S.C. § 371 of International Application No. PCT/EP2022/070297, filed Jul. 20, 2022, which claims the benefit of and priority to German Patent Application No. DE 10 2021 118 766.4, filed Jul. 20, 2021, the contents of which are hereby incorporated herein by reference in their entireties.

### TECHNICAL FIELD

The invention relates to a component with a component made of heat-treatable steel and/or of a low-alloy steel, in which the component is provided with an aluminum diffusion layer and an aluminum oxide layer. In particular, the invention can also relate to a fastening means, such as a screw or a nut, which has a component made of heat-treatable steel and/or of a low-alloy steel which is provided with an aluminum diffusion layer and an aluminum oxide layer.

### BACKGROUND

Metal components, especially high-strength and ultra-high-strength components made of heat-treated steel and/or low-alloy steel, are susceptible to hydrogen embrittlement. Hydrogen embrittlement is caused by the penetration of hydrogen into the metal structure of the components and leads to intergranular cracking when the components are stressed. This phenomenon is known as hydrogen-induced stress cracking corrosion.

### SUMMARY

A component with a component (1) of low-alloy steel and/or heat-treatable steel is provided, wherein the component (1) is at least partially coated with an aluminum diffusion layer (10) and an aluminum oxide layer (14) is applied to the aluminum diffusion layer (10), wherein the layer thickness of the aluminum diffusion layer (10) is 1-200 μm, wherein the aluminum diffusion layer (10) has an aluminum content, based on the total weight of the aluminum diffusion layer, of 10 wt. % above the aluminum content of the steel up to a maximum concentration, wherein the aluminum content in the aluminum diffusion layer (10) increases in the direction of the interface (12) between the aluminum diffusion layer (10) and the aluminum oxide layer (14) from 10% by weight up to the maximum concentration, and wherein the maximum concentration is 11-60% by weight.

### BRIEF DESCRIPTION OF THE DRAWINGS

FIG. 1 is a schematic view of a component according to the invention.

### DETAILED DESCRIPTION

The present invention is based on the task of reducing hydrogen embrittlement and thus the tendency to hydrogen-induced stress corrosion cracking in steel components.

This problem is solved with a component with a component made of a heat-treatable steel and/or a low-alloy steel according to claim 1, with a fastening means according to claim 2, with a method for manufacturing a component according to claim 8 and with a use according to claim 11. Further features, embodiments and advantages result from the subclaims, the description and the FIGURES.

One aspect of the invention relates to a component with a component made of quenched and tempered steel and/or of a low-alloy steel, wherein the component is at least partially coated with an aluminum diffusion layer and an aluminum oxide layer is applied to the aluminum diffusion layer, wherein the layer thickness of the aluminum diffusion layer is 1-200 μm, preferably 2-100 μm, particularly preferably 3-20 μm, wherein the aluminum diffusion layer has an aluminum content based on the total weight of the aluminum diffusion layer, of 10 percent by weight above the aluminum content of the steel up to a maximum concentration, wherein the aluminum content in the aluminum diffusion layer increases in the direction of an interface between the aluminum diffusion layer and the aluminum oxide layer from 10 percent by weight above the aluminum content of the steel up to the maximum concentration, and wherein the maximum concentration is 11-60 percent by weight.

A further aspect of the invention can relate to a component with a component made of heat-treatable steel and/or a low-alloy steel, wherein the component is a fastening means, wherein the steel component has and/or forms a threaded region, wherein the component, in particular in the threaded region, is at least partially coated with an aluminum diffusion layer and an aluminum oxide layer is applied to the aluminum diffusion layer, wherein the layer thickness of the aluminum diffusion layer is 1-200 μm, preferably 2-100 μm, is at least partially coated with an aluminum diffusion layer and an aluminum oxide layer is applied to the aluminum diffusion layer, wherein the layer thickness of the aluminum diffusion layer is 1-200 μm, preferably 2-100 μm, wherein the aluminum diffusion layer has an aluminum content, based on the total weight of the aluminum diffusion layer, of 10 wt.-% above the aluminum content of the steel up to a maximum concentration, wherein the aluminum content in the aluminum diffusion layer increases in the direction of an interface between the aluminum diffusion layer and the aluminum oxide layer from 10% by weight above the aluminum content of the steel up to the maximum concentration, and wherein the maximum concentration is 11-60% by weight. The fastening means is expediently a screw, in particular a high-strength or even an ultra-high-strength screw, or a nut, in particular a high-strength or even an ultra-high-strength nut.

A further aspect of the invention relates to a method of manufacturing a component with a component made of a heat-treatable steel and/or a low-alloy steel, comprising the steps of.
a) Providing a component with a component made of a heat-treatable steel and/or a low-alloy steel,
b) Application of an aluminum diffusion layer with a thickness of 1-200 μm on the component at a temperature of 400 to 1100° C. in an inert gas atmosphere,
c) Heating the component to 700 to 1000° C. in an oxygen-containing atmosphere for at least 10 minutes, which produces an aluminum oxide layer on the aluminum diffusion layer.

A further aspect of the invention relates to the use of the component according to the invention for reducing hydrogen embrittlement.

Surprisingly, the aluminum diffusion layer according to the invention in combination with the aluminum oxide layer acts as a very effective barrier against the penetration of hydrogen by diffusion on components made of heat-treatable steel and/or low-alloy steel, thereby increasing the resistance of the components to hydrogen-induced stress corrosion. The diffusion process and thus the formation of the aluminum diffusion layer also improves the adhesion of the aluminum layer to the steel, as the aluminum layer grows together with the steel of the component, so to speak.

Reducing hydrogen-induced stress corrosion is particularly advantageous and desirable for fasteners made of low-alloy steels, which usually exhibit or are exposed to high and often dynamic axial stress, because these fasteners, which can be bolts or nuts, for example, are essential for many assemblies. For example, the failure of a fastener, in particular a high-strength or ultra-high-strength bolt, can therefore have drastic consequences for man or machine, such as in the case of an engine head bolt, a bridge bolt, a cylinder head bolt, chassis bolt and/or battery fastening bolt. The invention can thus also relate to a vehicle, an engine, in particular a cylinder head, a chassis arrangement or a battery arrangement with a component, in particular a fastening means, with the aluminum diffusion layer according to the invention or a structure, in particular such as a bridge, or a vehicle.

Advantageously, the steel component is coated with the aluminum diffusion layer in areas with increased notch effect and/or adjacent areas to areas with increased notch effect, in particular in areas of a thread, under a head, e.g. of a screw, notches or grooves. Areas with an increased notch effect are in particular areas which have a notch effect factor of more than 1.1, preferably more than 1.4, particularly preferably more than 1.9 and most preferably more than 2.1. In an area of a thread, a groove or under a (screw) head or in the transition to the screw head, an area with an increased notch effect within the meaning of the invention is therefore advantageously to be seen. An adjacent area to an area with increased notch effect is to be understood as an area which is at a maximum distance of 10 mm, preferably at a maximum distance of 5 mm and particularly preferably at a maximum distance of 2 mm, from the area with increased notch effect. Alternatively, an adjacent area to an area with increased notch effect can also be present if it is at a maximum distance of 10%, preferably at a maximum of 5%, particularly preferably at a maximum of 2%, of the largest main dimension of the steel component from the area with increased notch effect.

All known aluminum coating processes and alitizing processes are suitable for producing the aluminum diffusion layer, provided that the processes can be carried out at a temperature in the range of 400 to 1100° C. so that an aluminum diffusion layer can be produced. Preferred processes are hot-dip aluminizing, chemical vapor deposition (CVD) and the slurry process. Chemical vapor deposition (CVD) is particularly preferred.

The aluminum diffuses into the iron lattice of the steel due to the increased temperature of 400 to 1100° C. in an inert gas atmosphere, creating the aluminum diffusion layer. In particular, the aluminum can react with the iron to form an intermetallic phase (so-called aluminide phase). In addition to the iron, any alloy components of the steel also diffuse into the aluminum-containing layer. The aluminum diffusion layer has a concentration gradient in which the aluminum concentration increases in the direction of the surface of the aluminum diffusion layer. After the aluminum oxide layer has been produced, this surface is the interface between the aluminum diffusion layer and the aluminum oxide layer. The iron concentration decreases in the same direction. Furthermore, the concentration of any alloy components of the steel decreases in this direction. The surface and/or the interface is, in particular, the surface which delimits the aluminum diffusion layer distally opposite or facing away from the steel component.

In the subsequent heating step of the component in an oxygen-containing atmosphere, the aluminium oxidizes on the surface and forms an aluminium oxide layer on the aluminium diffusion layer (oxidation step). This aluminum oxide layer acts as an additional hydrogen barrier and also serves as corrosion protection. The surface of the aluminum oxide layer can itself be coated and/or the surface can, for example, be a free surface that is not coated. In other words, the surface can be exposed or covered by a coating and/or by another component.

For the purposes of the invention, the aluminum diffusion layer is defined as the range of the tempered steel or low-alloy steel component having an aluminum content, based on the total weight of the aluminum diffusion layer, of 10% by weight above the aluminum content of the steel up to a maximum concentration, the maximum concentration being 10-60% by weight of aluminum. If, for example, the steel used does not contain any aluminum, the aluminum diffusion layer is the layer that has an aluminum content of 10% by weight up to the maximum concentration of aluminum. In this case, for a steel without aluminum content, the aluminum concentration in the aluminum diffusion layer is between 10% and 60% by weight.

If the steel of the component of the component is an alloy steel with an aluminum content of, for example, 1% by weight, the aluminum content in the aluminum diffusion layer is 11% by weight up to the maximum concentration. If the maximum concentration on the surface is 60% by weight, the aluminum content in the aluminum diffusion layer is therefore 11-60% by weight.

Preferably, the aluminum oxide layer is formed in direct contact with the aluminum diffusion layer. In other words, as in particular already described, no further layer is present between the aluminum oxide layer and the aluminum diffusion layer. Advantageously, at least 90%, particularly preferably at least 95% and particularly strongly preferably at least 99% of the aluminum diffusion layer, or its interface, is covered by the aluminum oxide layer. This enables particularly good and extensive shielding of the diffusion layer to be achieved.

A component made of quenched and tempered steel or low-alloy steel within the meaning of the invention can be understood in particular to mean that at least a part of the component, i.e. a volume region, is made of quenched and tempered steel or low-alloy steel. A quenched and tempered steel is a steel which obtains or exhibits high tensile and fatigue strength by quenching and tempering, in particular in the form of hardening and/or tempering. It is particularly preferred if the weight of the component consists of at least 80%, preferably at least 90%, and particularly strongly preferred at least 95%, of heat-treated steel or low-alloy steel or is formed by the component from heat-treated steel or low-alloy steel. This allows a particularly good mechanical strength of the component, especially of the fastener, to be achieved. In order to increase the mechanical strength, it is particularly preferable if the steel component is in one piece or in several parts. The term “one-piece” can be understood in particular to mean that at least the one-piece part has been created in a primary forming process and/or is cohesive.

For the purposes of the invention, “coated” with an aluminum diffusion layer means that the steel component has an aluminum diffusion layer on the outside in cross-section. This means in particular that the steel component is bordered in at least one spatial direction by a firmly adhering layer of shapeless material, which is an aluminum diffusion layer. Advantageously, the coating can comply with DIN 8580—especially in the version valid on May 1, 2021.

According to the invention, the thickness of the aluminum diffusion layer is 1-200 μm, preferably 2-100 μm, particularly preferably 3-50 μm and most preferably 3-20 μm. The lower thicknesses of the preferred embodiments of the aluminum diffusion layer are particularly advantageous for precisely fitting components. Preferably, the aluminum oxide layer is applied directly to the aluminum diffusion layer. This means that there is no other layer between the aluminum diffusion layer and the aluminum oxide layer.

The generation of the aluminum oxide layer is determined, among other things, by the duration and temperature of the heating step in an oxygen-containing atmosphere (oxidation step). The thickness of the aluminum oxide layer is preferably 1-5000 nm (nanometers), preferably 100-2000 nm, particularly preferably 500-1000 nm. With these layer thicknesses, a particularly effective barrier against the penetration of hydrogen and thus a particularly effective reduction in hydrogen embrittlement is achieved.

The “layer thickness” of the aluminum diffusion layer and the aluminum oxide layer is understood to be the average layer thickness if the top or bottom side has unevenness. For this purpose, at least three measurements of the layer thickness are taken, preferably 6 to 8 measurements, and the arithmetic mean of the measured values is determined.

The barrier effect against the penetration of hydrogen is achieved with the present invention by the combination of an aluminum diffusion layer and an aluminum oxide layer. A ratio of the layer thickness of the aluminum diffusion layer to the layer thickness of the aluminum oxide layer of 0.2-2,000,000 has proven to be advantageous, further preferably of 0.5 to 2000. This layer thickness ratio leads to a particularly effective reduction in hydrogen embrittlement, with simultaneously excellent adhesion of the aluminum diffusion layer to the low-alloy steel and/or quenched and tempered steel and a durable aluminum oxide layer which is effective as a barrier and is corrosion-resistant.

The maximum concentration of aluminum in the aluminum diffusion layer is 11-60% by weight. Preferred is 11-50 wt. %, particularly preferred 11-35 wt. %, further preferred 12-35 wt. %, still further preferred 15-35 wt. %, in particular 18-30 wt. %. These maximum concentrations of aluminum in the aluminum diffusion layer lead to a pronounced formation of iron aluminide phases (FeAl), which are particularly effective in preventing hydrogen embrittlement.

The proportion of aluminum in the aluminum diffusion layer increases in the direction of the interface between the aluminum diffusion layer and the aluminum oxide layer. The increase takes place from 10 wt. % above the aluminum content of the steel up to the maximum concentration, for example 11-60 wt. %. Preferably, the aluminum content in the aluminum diffusion layer increases vertically in the direction of the interface between the aluminum diffusion layer and the aluminum oxide layer. It is further preferred that the aluminum content in the aluminum diffusion layer increases perpendicularly in the direction of the interface between the aluminum diffusion layer and the aluminum oxide layer. Preferably, intermetallic phases are formed in the aluminum diffusion layer, which are preferably intermetallic iron aluminide phases (FeAl). These are preferably formed by setting the maximum concentration of the aluminum in the aluminum diffusion layer in the preferred ranges, e.g. 11-50 wt. %, particularly preferably 11-35 wt. %, even more preferably 12-35 wt. %, still more preferably 15-35 wt. %, in particular 18-30 wt. % maximum concentration of the aluminum in the aluminum diffusion layer.

In a preferred embodiment of the invention, the control of the Al activity can be adjusted during the production of the aluminum diffusion layer depending on the coating process, e.g. in the slurry process, Al powder can be mixed with Si in order to reduce the Al activity or in the CVD process, the ratio of the so-called packing mixture (filler Al O23 e.g. 85 wt. %, plus halogen-containing activator (e.g. 6%), such as NH4 Cl, and e.g. 9% Al powder). These processes lead to the increased formation of intermetallic phases, which are preferably intermetallic iron-aluminide phases (FeAl).

The aluminum oxide layer can at least partially form the surface of the component. In order to further adapt the surface of the component to the respective application, it is preferred that a further layer is applied to the aluminum oxide layer, preferably selected from wear protection layer and sliding layer. Phosphate layers and zinc flakes are preferred, especially if the component is a fastener, preferably a screw or bolt. These layers are particularly advantageous in terms of improving the friction properties.

The steel of the component of the part is a low-alloy steel and/or quenched and tempered steel. For the purposes of the invention, a low-alloy steel is understood to be a steel whose total proportion of alloying elements does not exceed 5% by weight, in particular of the alloying elements Cr, Mo, V, Ni, Mn, Al, B and Ti, based on the total weight of the steel. The term low-alloy steel within the meaning of the invention thus also includes unalloyed steels and micro-alloyed steels. For the purposes of the invention, an unalloyed steel is understood to be a steel that contains up to 0.8% by weight of carbon and less than 1% by weight of manganese, based on the total weight of the steel.

In a preferred embodiment of the invention, the low-alloy steel of the component of the component, which may also be a non-alloy steel, is preferably a high-strength or ultra-high-strength steel. In particular, it may be a low-alloy quenched and tempered steel. Low-alloy steels can be tempered particularly well and at the same time or alternatively provide a particularly high degree of strength, so that the advantages achieved by the invention, in particular with regard to hydrogen embrittlement, can be used or achieved particularly well here.

In a preferred embodiment of the invention, the microstructure of the steel component in the component is at least predominantly martensitic, bainitic and/or dual-phase (retained austenite, ferrite and/or martensite). Preferably, the microstructure of the steel component in the component is at least 80% by weight, in particular at least 90% by weight martensitic, bainitic and/or dual-phase (retained austenite, ferrite and/or martensite), in each case based on the total weight of the steel component. These microstructures give the component according to the invention a particularly high strength and toughness. These microstructures can be subjected to high and also frequently dynamic axial stress, so that the reduction of hydrogen embrittlement is particularly advantageous for them. The microstructure in the aluminum diffusion layer can differ from the microstructure of the remaining steel component (the so-called base material). The element distribution in the aluminium diffusion layer is advantageously characterized by a high concentration of two elements, namely iron and aluminium. Depending on the composition of the steel component, the other alloying elements may be present as dissolved elements or as intermetallic precipitates in the aluminum diffusion layer.

The component according to the invention is preferably a high-strength or ultra-high-strength component, in particular with strengths above 1000 MPa, preferably above 1200 MPa, particularly preferably above 1400 MPa and particularly strongly preferred above 1600 MPa. Preferred high-strength and ultra-high-strength components are high-strength or ultra-high-strength screws or fasteners, springs, leaf springs, disk springs and chain drives, formed components and/or structural components. Further or alternatively preferred is the component according to the invention, in particular the high-strength or ultra-high-strength component, preferably a welded component, an additive-manufactured component or a case-hardened component. Welded components in particular can be subject to high hydrogen embrittlement due to welding, so that the invention can be used particularly well here. In the case of a case-hardened component, the component is additionally case-hardened during manufacture, in particular by carburizing, nitriding or nitrocarburizing. The component is then provided with the aluminum diffusion layer, as described above.

A formed component is in particular a component which has been formed by means of a forming step, in particular a cold forming process. Especially in the case of a formed component, in particular a cold-formed component, it is particularly advantageous to avoid brittleness, in particular hydrogen embrittlement, because a certain degree of brittleness already exists in a formed component due to the accumulated forest dislocations. A structural component within the meaning of the invention is present in particular if the component is a load-bearing component. In particular, this structural component has two load-introducing sections, which advantageously have load-introducing structures, such as mounting recesses or openings, and a transmission area arranged between the load-introducing sections, which can and/or does transmit a load, in particular a bending load, from one load-introducing section to the other load-introducing section. Advantageously, at least one, preferably all load introduction sections, and/or the transmission area is provided with the aluminum diffusion layer according to the invention. Forming the component in such a way that the steel has a strength of over 1000 MPa, preferably over 1200 MPa, particularly preferably over 1400 MPa and particularly strongly preferably over 1600 MPa, is particularly advantageous, since hydrogen embrittlement is always more decisive in these strength classes, so that the invention can play out its advantages precisely at these strengths.

In a preferred embodiment, the invention relates to a component with a component made of a heat-treatable steel and/or a low-alloy steel,
where the component is a fastener,
wherein the component has and/or forms a threaded portion and/or shank portion,
wherein the component is at least partially coated with an aluminum diffusion layer, in particular in the thread region and/or shank region, and an aluminum oxide layer is applied to the aluminum diffusion layer, wherein the layer thickness of the aluminum diffusion layer is 1-200 μm,
wherein the aluminum diffusion layer has an aluminum content, based on the total weight of the aluminum diffusion layer, of 10% by weight above the aluminum content of the steel up to a maximum concentration,
wherein the aluminum content in the aluminum diffusion layer increases in the direction of an interface between the aluminum diffusion layer and the alumina layer from 10% by weight above the aluminum content of the steel to the maximum concentration, and the maximum concentration is 11-60% by weight, wherein the component is a high-strength or ultra-high-strength component.

The fastening means according to the invention can in particular be non-positive fastening means, such as screws, bolts or nuts. Force-locking fastening means are characterized in particular by the fact that they have a threaded section for bracing or fastening, in particular with an external thread or an internal thread. For example, the threaded section can therefore be an external thread or an internal thread. Advantageously, this threaded section is incorporated in a component of the fastening means, which is made of steel. In other words, the steel component can have a threaded section which can be coated with the aluminum diffusion layer described above and below. Advantageously, at least three, preferably at least five, and particularly preferably all threads of the threaded portion are coated with the aluminum diffusion layer. Advantageously, at least the distal end threads are the threads that are coated with the aluminum diffusion layer. The end threads are in particular the threads that form one end of the threaded section or form the end regions of the threaded section or the thread run-out. Alternatively, or additionally preferably, the aluminum diffusion layer can also be present in a shank area. The shank area is in particular an area of the fastener which lies between the head, in particular the screw head, and the threaded section of the fastener and mechanically connects them to one another. Preferably, the shank area can be threadless and/or designed as a cylindrical section. The diameter of the shank can be less than or equal to the thread diameter in the threaded section. By applying or forming an aluminum diffusion layer—as described above and below—in the shank area, the mechanical properties of the fastener can be positively influenced there in accordance with the invention. The screws are advantageously high-strength or ultra-high-strength screws.

The steel component in the component according to the invention is at least partially coated with an aluminum diffusion layer, i.e. the component is partially or completely coated with an aluminum diffusion layer.

In a particularly preferred embodiment of the invention, the component is a high-strength or ultra-high-strength screw. A high-strength screw is understood to be a screw with a tensile strength of at least 800 MPa. High-strength screws are, for example, screws of strength classes 8.8, 10.9 and 12.9. In particular, the strength classes of the invention correspond to ISO 898-1 in its version valid in January 2021. An ultra-high-strength screw is understood to be a screw with a tensile strength of at least 1200 MPa and/or advantageously 1400 MPa. Ultra-high-strength screws are, for example, screws of strength classes 12.8, 12.9, 14.8, 14.9, 15.8, 15.9, 16.8, 16.9, 17.8 and 12.8U, 12.9U, 14.8U, 14.9U, 15.8U, 15.9U, 16.8U, 17.8U. A high-strength screw is a screw that is at least high-strength, but it can also be ultra-high-strength. Preferably, it is a high-strength or ultra-high-strength screw with a strength of over 1000 MPa. The component of the component or the screw which has the aluminum diffusion layer is particularly preferably the shank and/or the threaded area of the screw, because it is precisely here that strong dynamic loads occur during operation of the screw, which increase the susceptibility of the screw to hydrogen embrittlement, which can be prevented or at least significantly reduced by the invention. The screw can have a head with tool-engaging surfaces, whereby these tool-engaging surfaces form an internal or external hexagon in particular. It is particularly preferred if the entire screw is coated with the aluminum diffusion layer.

The invention also relates to a method for manufacturing the component according to the invention. The method according to the invention for manufacturing a component with a component made of a heat-treatable steel and/or a low-alloy steel, comprises the steps:
a) Providing a component with a component made of a heat-treatable steel and/or a low-alloy steel,
b) Application of an aluminum diffusion layer with a thickness of 1-200 μm on the component at a temperature of 400 to 1100° C. in an inert gas atmosphere,
c) Heating the component to 700 to 1000° C. in an oxygen-containing atmosphere for at least 10 minutes, which produces an aluminum oxide layer on the aluminum diffusion layer.

The temperature in step b) is preferably at 800-1000° C.

Preferably, heating takes place in heating step c) for at least 15 minutes, preferably for at least 20 minutes and most preferably for at least 30 minutes. It is further preferred that the heating takes place for 10-600 minutes, particularly preferably for 15-400 minutes and most preferably for 20-180 minutes. The heating in step c) takes place at 700-1000° C. for the specified periods of time, preferably at 800-1000° C., particularly preferably at 820-980° C.

The aluminum diffusion layer is preferably applied by applying an aluminum layer, which then forms an aluminum diffusion layer at the temperature of step b), preferably a temperature of 400 to 1100° C.

The method according to the invention for manufacturing a component with a component made of a heat-treatable steel and/or a low-alloy steel thus comprises the steps:
a) Providing a component with a component made of a heat-treatable steel and/or a low-alloy steel,
b) Application of an aluminum layer on the component at a temperature of 400 to 1100° C. in an inert gas atmosphere, whereby an aluminum diffusion layer with a layer thickness of 1-200 μm is formed on the component,
c) Heating the component to 700 to 1000° C. in an oxygen-containing atmosphere for at least 10 minutes, which produces an aluminum oxide layer on the aluminum diffusion layer.

For the purposes of the invention, an inert gas atmosphere is understood to be an atmosphere of a gas or gas mixture which is inert to the aluminum of the aluminum diffusion layer. Preferably, it is a gas atmosphere which contains less than 1% by volume of gases which are reactive towards aluminum, in particular less than 1% by volume of oxygen. Particularly preferably, the inert gas atmosphere comprises more than 99% by volume of nitrogen, hydrogen and/or noble gases, for example argon, argon and nitrogen, or nitrogen and hydrogen, e.g. nitrogen and 5-10% H2.

A preferred embodiment of the invention relates to a method of manufacturing a component, wherein the component is a high-strength or ultra-high-strength component, comprising the steps of.
a) Providing a component, wherein the component is a high-strength or ultra-high-strength component, which is a fastener having and/or forming a threaded portion and/or shank portion, with a component of a heat-treatable steel and/or a low-alloy steel,
b) Application of an aluminum diffusion layer with a layer thickness of 1-200 μm on the component, in particular in the thread area and/or shank area, at a temperature of 400 to 1100° C. in an inert gas atmosphere,
c) Heating the component to 700 to 1000° C. in an oxygen-containing atmosphere for at least 10 minutes, which produces an aluminum oxide layer on the aluminum diffusion layer.

Heating step c) may be followed by further steps, in particular heat treatment step d). Alternatively, or additionally preferably, however, the tempering step can also take place during and/or at the same time or together with the heating step c). In other words, tempering and heating/oxidizing can be carried out together in one step. In this way, a particularly fast and cost-effective production of the aluminum oxide layer can be achieved. For example, martensitic quenching and tempering (preferably by quenching in oil, air and/or water) or bainitization (preferably in a salt bath) can be carried out. Martensitic quenching and tempering or bainitization are carried out under the usual conditions.

Heating step c) can therefore be a separate heating step, for example in a furnace, or the heating step can take place during the tempering step of the component, for example during austenitization of the steel. Preferably, the heating step takes place during the hardening and tempering of the component.

In a preferred embodiment of the invention, the method of manufacturing the component according to the invention therefore comprises the steps of.
a) Providing a component with a component made of a heat-treatable steel and/or a low-alloy steel,
b) Application of an aluminum diffusion layer with a thickness of 1-200 μm on the component at a temperature of 400 to 1100° C. in an inert gas atmosphere,
c) Heating the component to 700 to 1000° C. during annealing of the component in an oxygen-containing atmosphere for at least 10 minutes, whereby an aluminum oxide layer is produced on the aluminum diffusion layer.

Steps a), b) and c) above are carried out in this order.

The invention also relates to the use of the component according to the invention for avoiding or reducing hydrogen embrittlement. The use preferably comprises the use of the described, preferred components for avoiding or reducing hydrogen embrittlement, for example a fastener having a threaded portion and/or shank portion. This relates in particular to the reduction or avoidance of hydrogen embrittlement in the component due to hydrogen that can penetrate from the outside, for example when the component is used as intended. This can be the case, for example, when the component according to the invention, such as a fastener, is used in a corrosive environment. The aluminum diffusion layer according to the invention in combination with the aluminum oxide layer then protects the component particularly effectively against hydrogen embrittlement by reducing or preventing the penetration of hydrogen into the component.

A preferred embodiment of the invention relates to the use of the component according to the invention, in particular fastening means, in a fuel cell or a battery arrangement. In fuel cells or batteries, a relatively large amount of hydrogen is often produced and here the aluminum diffusion layer according to the invention in combination with the aluminum oxide layer can prevent hydrogen embrittlement with particular advantage.

The invention also relates to a battery arrangement and/or fuel cell, comprising a component according to the invention, in particular a fastening means according to the invention. Here, the advantages of avoiding hydrogen embrittlement described above are achieved particularly effectively due to the relatively high quantities of hydrogen produced in battery arrangements or fuel cells.

The advantageous embodiments of the process according to the invention described above are also advantageous for this preferred process, in particular the mentioned preferred and particularly preferred layer thicknesses, temperatures, heating times and/or advantageous components etc.

The microstructure of the steel component before heating step c) can be ferritic, ferritic-pearlitic, bainitic, GKZ-annealed or a mixed microstructure. After heat treatment step d), the microstructure of the component can, in a preferred embodiment, be martensitic, bainitic or ferritic-martensitic or dual-phase (retained austenite, ferrite and/or martensite).

The invention also relates to a component with a component made of steel, obtainable by the method according to the invention. Advantageously, the component and/or the component made of steel may also have the aforementioned features with regard to the method.

It is understood that the features mentioned above and those to be explained below can be used not only in the combinations indicated, but also in other combinations or in a stand-alone position, without going beyond the scope of the present invention. The aforementioned advantages of features or of combinations of several features are merely exemplary and can take effect alternatively or cumulatively. The combination of features of different embodiments of the invention or of features of different patent claims is possible in deviation from the selected references of the patent claims.

Measuring method for determining coating thickness:

The thickness of the aluminum diffusion layer is preferably measured with a micrometer, for example using the method according to ASTM C664-10 (as published in 2020, test method A). For this purpose, the thickness of the component before and after coating with the aluminum diffusion layer is essentially measured and the difference results in the layer thickness.

The thickness of the aluminum diffusion layer can also be determined by first measuring the thickness of the component after it has been coated with the aluminum diffusion layer. The aluminum diffusion layer is then removed, for example by grinding, and the composition of the material is analyzed, for example by chemical analysis of the removed material or chemical analysis of the remaining surface material. Wet chemical methods, atomic force microscopy (AFM) or energy dispersive X-ray spectroscopy (EDS, EDX, EDXS or XEDS) can be used as analysis methods, for example. Material is removed as long as the removed material has an aluminum content of at least 10% by weight above the aluminum content of the steel, based on the total weight of the aluminum diffusion layer. After removal of the aluminum diffusion layer, the aluminum content of the steel on the surface of the component is just below 10% by weight above the aluminum content of the steel and the thickness of the component is measured again with a micrometer. The thickness of the aluminum diffusion layer is calculated from the difference.

Alternatively, the thickness of the aluminum diffusion layer can be determined using the method according to ASTM C664-10 (as published in 2020, test method B). For this purpose, the layer thickness is essentially determined in cross-section using an optical microscope. It is also possible to determine the thickness of the aluminum diffusion layer in the cross-section using energy dispersive X-ray spectroscopy (EDS, EDX, EDXS or XEDS). The thickness of the aluminum oxide layer can be determined using scanning electron microscopy.

A component with an aluminum diffusion layer is manufactured by producing the component from the substrate material steel using axial cold forging. The starting material is fed to the forming machine in the form of a coil of wire. The formed product has the geometry of a screw. An aluminum diffusion coating is then applied. After the coating has been applied, the component is heated in an oxygen-containing atmosphere and austenitized at a temperature of 850° C. for 30 minutes for tempering.

To set the desired microstructure and mechanical properties of the component, quenching is carried out immediately after austenitizing. A suitable microstructure is set during the quenching process. Within the diffusion layer, the material produced transforms according to its local Al concentration. The resulting component had a tensile strength of 1600 MPa-1650 MPa.

Experimental evaluation of the influence of the aluminum diffusion layer on hydrogen-induced stress corrosion cracking:

The phenomenon of hydrogen-induced stress corrosion cracking in high-strength steel materials generally requires three external influencing factors. These are:
1. Material with a susceptibility to hydrogen-induced stress corrosion cracking
2. High mechanical tensile or bending stresses in the component
3. Hydrogen supply in the surrounding area

To evaluate the material behavior with regard to hydrogen-induced stress corrosion cracking, a test setup is therefore suitable in which the other two factors are reproducibly mapped. The test setup according to DIN EN ISO 7539-7 is therefore used for the assessment.

The evaluation in accordance with DIN EN ISO 7539-7 chapter 7.3 according to “Integral of the nominal stress/strain curve” has proven to be particularly precise. In any case, the system consisting of the above-mentioned influencing factors in the state without hydrogen supply in the environment is always compared with the system with hydrogen supply in the environment for characterization. After evaluating the characteristic value of the “integral of the nominal stress/strain curve”, a value for the total deformation energy absorbed by the component is obtained for each of the two states. By using the formula

$$HE = 1 - \frac{{W}_{Bh} ( Deformation energy including H - load )}{{W}_{Bu} ( Deformation energy excluding H - load )}$$

the so-called HE value is determined from the two calculated deformation energies. The HE value can be between 0 and 1. A value of HE=0 means no influence on the material properties, while HE=1 means failure under hydrogen without load (the latter is a theoretical extreme value and not possible in reality).

The screws with an integrated aluminium diffusion layer are characterized by determining the reference value without hydrogen load WBu. This is determined using the mean value of three samples with an elongation rate of 0.0067 1/s in the instrumented tensile/compression testing machine. The screws according to the invention showed no significant drop in strength after exposure to hydrogen, whereas screws not coated according to the invention showed such a drop.

Further advantages and features of the present invention are shown in the following description with reference to the FIGURES. Individual features of the embodiments shown can also be used in other embodiments, unless this has been expressly excluded. It shows:

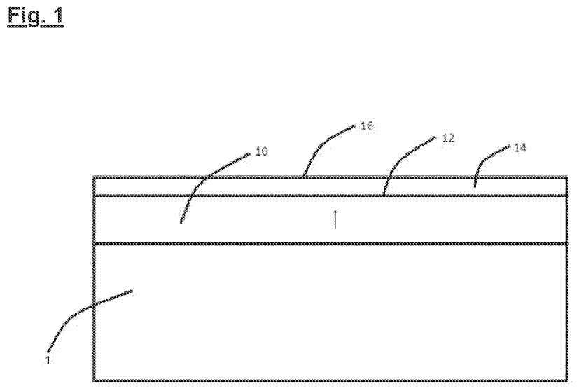

FIG. 1 shows a component according to the invention. The component has a component 1 made of low-alloy steel and/or heat-treated steel. In particular, the component can be a fastener or a spring. The component 1 is at least partially coated with an aluminum diffusion layer 10, whereby the thickness of the aluminum diffusion layer is 1 to 200 μm. The arrow in the aluminum diffusion layer 10 of FIG. 1 indicates the decrease in the concentration of aluminum in the aluminum diffusion layer 10 as well as the thickness direction in which the thickness of the aluminum diffusion layer 10 can be determined in particular. An aluminum oxide layer 14 is applied to the aluminum diffusion layer 10. The aluminum diffusion layer is bounded distally opposite the steel component 1 by the interface 12 between the aluminum diffusion layer 10 and the aluminum oxide layer 14. This surface 16 of the aluminum oxide layer 14 can itself be coated.

1. A component with comprising:
a component made of a heat treatable steel and/or a low alloy steel,
wherein the component is at least partially coated with an aluminum diffusion layer and an aluminum oxide layer is applied to the aluminum diffusion layer,
wherein the layer thickness of the aluminum diffusion layer is 1-200 μm,
wherein the aluminum diffusion layer has an aluminum content, based on the total weight of the aluminum diffusion layer, of 10% by weight above the aluminum content of the steel up to a maximum concentration, and
wherein the aluminum content in the aluminum diffusion layer increases in the direction of an interface between the aluminum diffusion layer and the aluminum oxide layer from 10% by weight above the aluminum content of the steel up to the maximum concentration, and the maximum concentration is 11-60% by weight.

2. The component of claim 1, wherein the component is a fastener,
wherein the component has and/or forms a threaded area, and
wherein the component is at least partially coated in the threaded area the aluminum diffusion layer.

3. The component of claim 1, wherein the aluminium oxide layer is applied directly to the aluminium diffusion layer.

4. The component of claim 1, wherein the layer thickness of the aluminium diffusion layer is 2-100 μm and/or the layer thickness of the aluminium oxide layer is 100-2000 nm.

5. The component of claim 1, wherein the aluminium diffusion layer comprises intermetallic phases.

6. The component of claim 1, wherein the component is selected from the group consisting of screws, springs, leaf springs, disc springs and chain drives.

7. The component of claim 1, wherein the low alloy steel is an unalloyed steel.

8. A method of manufacturing a component, comprising the steps of:
providing a component with a component made of a heat treatable steel and/or a low alloy steel;
application of an aluminum diffusion layer with a layer thickness of 1-200 μm on the component at a temperature of 400 to 1100° C. in an inert gas atmosphere;
heating the component to 700 to 1000° C. in an oxygen containing atmosphere for at least 10 minutes, thereby producing an aluminum oxide layer on the aluminum diffusion layer.

9. The method of claim 8, wherein the heating takes place during the tempering of the component.

10. The method of claim 8, wherein the component is at least partially coated with an aluminum diffusion layer and an aluminum oxide layer is applied to the aluminum diffusion layer.

11. The method of claim 8, wherein the component is configured for reducing hydrogen embrittlement.

12. The method of claim 11, wherein the component is configured for use in a battery assembly and/or fuel cell.

13. The method of claim 8, wherein the component comprises a fastening means.

14. A component comprising:
a fastener made of a steel,
wherein the fastener has a threaded area,
wherein the fastener is at least partially coated in the threaded area with an aluminum diffusion layer having a layer thickness of 1-200 μm,
wherein an aluminum oxide layer is applied to the aluminum diffusion layer,
wherein the aluminum diffusion layer has an aluminum content, based on the total weight of the aluminum diffusion layer, of 10% by weight above the aluminum content of the steel up to a maximum concentration,
wherein the aluminum content in the aluminum diffusion layer increases in the direction of an interface between the aluminum diffusion layer and the aluminum oxide layer from 10% by weight above the aluminum content of the steel up to the maximum concentration, and
wherein the maximum concentration is 11-60% by weight.

15. The component of claim 14, wherein the aluminium oxide layer is applied directly to the aluminium diffusion layer.

16. The component of claim 14, wherein the layer thickness of the aluminium diffusion layer is 2-100 μm and/or the layer thickness of the aluminium oxide layer is 100-2000 nm.

17. The component of claim 14, wherein the aluminium diffusion layer comprises intermetallic iron aluminide phases.

18. The component of claim 14, wherein the fastener is a high strength or ultra high strength component.

19. The component of claim 14, wherein the steel is an unalloyed steel.
